(19) United States
(12) Patent Application Publication
(10) Pub. No.: US 2020/0158797 A1
(43) Pub. Date: May 21, 2020

(54) Augnment mangnetometer with angular offset between polarisations of the pump and probe beams

(71) Applicant: COMMISSARIAT À L'ÉNERGIE ATOMIQUE ET AUX ÉNERGIES ALTERNATIVES, Paris (FR)

(72) Inventor: François Beato, Grenoble Cedex 09 (FR)

(21) Appl. No.: 16/682,334

(22) Filed: Nov. 13, 2019

(30) Foreign Application Priority Data
Nov. 16, 2018 (FR) 1860642

(51) Int. Cl. G01R 33/26

(52) U.S. Cl. CPC G01R 33/26

(57) ABSTRACT

A magnetometer, comprising a cell filled with an atomic gas, an optical source configured to illuminate the cell with a pump beam and a probe beam and a photodetection device arranged so as to receive the light of the probe beam that has passed through the cell and configured to deliver a signal carrying information relating to the state of alignment of the atoms of the atomic gas in the cell. The pump beam is polarised linearly in a polarisation direction and the probe beam is polarised linearly in a polarisation direction forming a non-zero angle with the polarisation direction of the pump beam.

### TECHNICAL FIELD

The field of the invention is that of optical pumping magnetometers. The invention in particular, but not exclusively, finds an application for parametric-resonance magnetometers.

### PRIOR ART

Optical pumping magnetometers use atomic gases confined in a cell, typically metastable helium or alkali gases, as a sensitive element. These magnetometers, which may take various configurations, make it possible to go back to the magnetic field by using the following three processes, which take place either sequentially or concomitantly:
1) The use of polarised light sources, typically lasers, makes it possible to prepare atomic states characterised by a certain orientation or alignment of the spins thereof. This process has the name “optical pumping” in the field.
2) These atomic states change under the effect of the magnetic field, in particular under the Zeeman effect which corresponds to shifts in the energy levels according to the magnetic field to which the atoms are subjected.
3) The optical properties of the atomic medium then undergo modifications that are dependent on the state of the atoms. It is thus possible by an optical measurement, for example by an optical absorption measurement, to go back to the Zeeman shift undergone and to deduce from this a measurement of the magnetic field in which the cell is immersed.

According to the various possible configurations of the existing optical pumping magnetometers, there is a measurement of the modulus, also referred to as the norm, of the magnetic field for scalar magnetometers, or a determination of the various components of the magnetic field at the location of the cell for vector magnetometers.

In order to carry out a vectorial measurement of the magnetic field with a wide bandwidth, there exist two well known configurations: the first known as “Hanle effect” and the second known as “parametric resonance”. These configurations are described in particular in the article by J. Dupont-Roc, “Détermination par des méthodes optiques des trois composantes d'un champ magnétique très faible”, Revue de Physique Appliquee, vol. 5, no. 6, pp. 853-864, 1970. They function at very low external magnetic field values, causing a weaker Zeeman shift than the degree of relaxation of the Zeeman sub-levels of the atom, which, for the case of helium, fixes a limit around 100 nanotesla, that is to say 500 times less intense than the earth's magnetic field.

The difference between these two configurations stems from the application (in parametric resonance) or not (Hanle effect) of one or two radio-frequency (RF) fields that make it possible to modulate the response of the system.

In the majority of prior works, the optical measurement is based on a measurement of absorption. For this type of measurement, the optimum signal-to-noise ratio is obtained by fixing the wavelength of the beam making the measurement (probe beam) at the centre of one of the atomic lines of the gas used. In this case, it is possible to merge the beam carrying out the optical pumping (pump bean) with the probe beam, if it is chosen to pump and probe via the same atomic line. Medical measurements using a parametric-resonance magnetometer using helium-4 pumped in alignment have shown that, at the present time, the sensitivity of the sensor is limited by the technical noises of the laser (cf. “Magnetocardiography measurements with 4He vector optically pumped magnetometers at room temperature”, Morales et al, 2017 Phys. Med. Biol. 62 7267).

In the case of magnetometers using alkali gases pumped in orientation using a circularly polarised pump beam, various documents (including for example J. C. Allred et al., “High-Sensitivity Atomic Magnetometer Unaffected by Spin-Exchange Relaxation,” Phys. Rev. Lett., vol. 89, no. 13, p. 130801, September 2002) describe another type of optical measurement. This measurement consists of sending a second linearly polarised beam slightly offset in wavelength with respect to an atomic transition. In this case, the measurement signal that makes it possible to go back to the atomic dynamic is the angle of rotation of the polarisation plane of the light.

This polarimetric measurement has the advantage of being a differential measurement, which makes it possible to be free from numerous technical noises. However, the rotation of the angular polarisation of the light that is used as a measuring signal is always zero in the case where the atoms are aligned under the effect of a linear-polarisation pumping, as is the case in particular in the article by Morales et al cited above.

However, it may be preferred to carry out such linear-polarisation pumping in order to disregard undesirable effects of a circular-polarisation pumping that introduce significant defects in the functioning of a magnetometer, in particular the effect known as “light shift” or “AC-Stark shift”, according to which circularly polarised light that is not perfectly tuned to an atomic transition behaves as a false magnetic field disturbing the behaviour of the atoms.

### DISCLOSURE OF THE INVENTION

The objective of the invention is to carry out a differential polarimetric measurement of a state of alignment of the atoms obtained by means of a linear-polarisation pumping. For this purpose, the invention proposes a magnetometer comprising a cell filled with an atomic gas, an optical source configured to illuminate the cell with a pump beam and a probe beam and a photodetection device arranged so as to receive the light of the probe beam that has passed through the cell and configured to deliver a signal carrying information relating to the state of alignment of the atoms of the atomic gas in the cell. The pump beam is polarised linearly in a polarisation direction and the probe beam is polarised linearly in a polarisation direction forming a non-zero angle with the polarisation direction of the pump beam.

Certain preferred but non-limitative aspects of this magnetometer are as follows:
the probe beam propagates along the z axis of an Oxyz trihedron, the pump beam is polarised linearly along the x axis of the trihedron and the pump beam is polarised linearly in the Oxy plane, making said non-zero angle with the x axis;
said non-zero angle is chosen so that the signal delivered by the photodetection device is zero when there is a zero ambient magnetic field;
said non-zero angle is between 45° and 90°;
the pump beam is tuned for wavelength at the centre of a first atomic line and the probe beam is tuned for wavelength so as to be offset from the centre of a second atomic line different from the first atomic line, being for example tuned to the maximum of the imaginary part of the Voigt profile of the second atomic line;
the pump beam is tuned for wavelength at the centre of a first atomic line and the probe beam is tuned for wavelength so as to be offset from the centre of the first atomic line, being for example tuned for wavelength to the maximum of the imaginary part of the Voigt profile of the first atomic line;
it further comprises a parametric-resonance excitation source and the photodetection device comprises a polarisation analyser configured to make a differential measurement of the right-hand circular polarisation and of the left-hand circular polarisation of the probe beam that has passed through the cell;
the polarisation analyser comprises a quarter-wave plate, a polarisation separator able to separate, on a first path and a second path, the right-hand circular polarisation and the left-hand circular polarisation of the probe contribution that has passed through the cell and a photodetector on each of the first and second paths;
the photodetection device is configured to make an absorption measurement of the probe beam on passing through the cell;
it further comprises a modulator of the probe beam.

### BRIEF DESCRIPTION OF THE DRAWINGS

Other aspects, aims, advantages and features of the invention will emerge more clearly from a reading of the following detailed description of preferred embodiments thereof, given by way of non-limitative example, and made with reference to the accompanying drawings, on which:

FIG. 1 is a diagram of a magnetometer according to the invention;

FIG. 2 is a diagram of an example of the arrangement of the polarisation directions of the pump and probe beams;

FIG. 3 depicts the Voigt profile of an atomic transition line of helium-4;

FIG. 4 depicts a signal issuing from a differential measurement that can be carried out in the invention.

### DETAILED DISCLOSURE OF PARTICULAR EMBODIMENTS

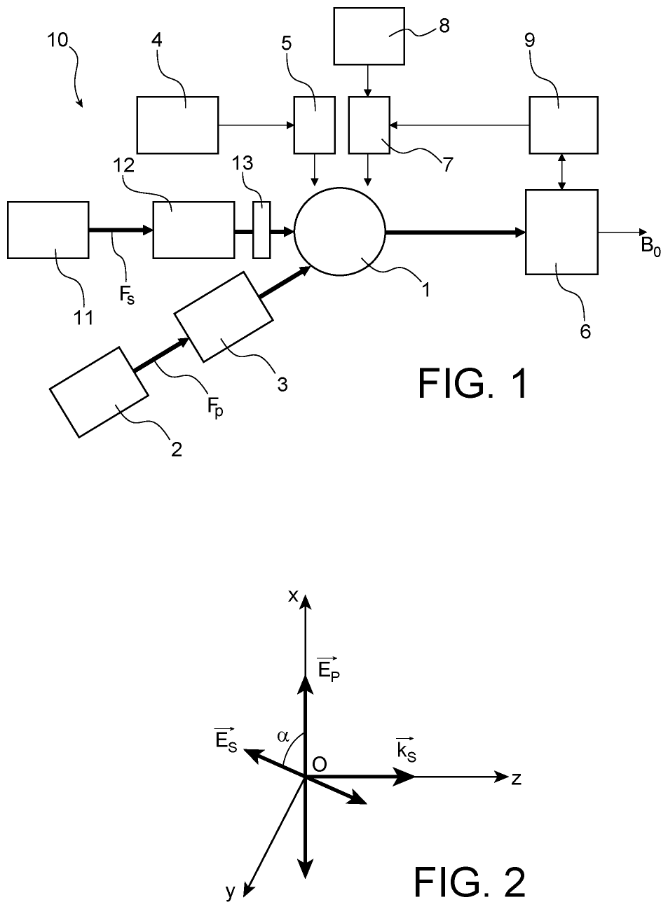

With reference to FIG. 1, the invention relates to an optical-pumping vector magnetometer 10 that comprises a cell 1 filled with an atomic gas able to be polarised in alignment, for example helium-4 or an alkali gas, and which is subjected to an ambient magnetic field B₀. The magnetometer 10 moreover comprises an optical source 2, 3, 11-13 configured to illuminate the cell and a detector 6 that receives light that has passed through the cell and delivers a signal carrying information relating to the state of alignment of the atoms of the atomic gas in the cell to a processing electronics that uses the signal to provide a measurement of the ambient field B₀.

In the case where the sensitive element is helium-4, the magnetometer 10 also comprises a high-frequency (HF) discharge system, comprising an HF generator 4 and overvoltage coils 5, to bring the atoms of the atomic gas into an energised state in which they are able to undergo an atomic transition, typically into the metastable state 2³S₁.

In the context of the invention, the optical source is configured to illuminate the cell with a pump beam and a probe beam. The pump beam is polarised linearly, which induces so-called “aligned” atomic states in the cell 1, the alignment axis being fixed by the direction of the electric field of the light used for pumping. The probe beam is polarised linearly in a polarisation direction forming a non-zero angle with the polarisation direction of the pump beam. By way of example, and with reference to FIG. 2, the propagation direction \vec{kₛ} of the probe beam is aligned along the z axis of a trihedron Oxyz, the polarisation direction Eₚ of the pump beam is aligned along the x axis of the trihedron and the polarisation direction Eₛ of the probe beam lies in the plane Oxy, forming a non-zero angle α with the x axis.

As depicted in FIG. 1, the cell is thus illuminated by an optical source that comprises a pumping element 2 able to emit the pump beam Fp in the direction of the cell 1 and a probing element 11 able to emit the probe beam Fs in the direction of the cell 1. These elements 2, 11 may be lasers, for example semiconducting diodes.

The pump beam Fp is polarised linearly along the x axis by means of a polarisation device 3 interposed between the pumping element 2 and the cell 1 or directly integrated in the pumping element 2. The probe beam Fs is polarised linearly along the x axis by means of a polarisation device 12 interposed between the probing element 11 and the cell 1 or directly integrated in the probing element 12. The probe beam Fs propagates along the z axis of the trihedron xyz and is made to pass through a polarisation rotator 13 before it enters the cell 1, so as to make its polarisation rotate in the plane xOy, this having, on emerging from the rotator, the non-zero angle α with the x axis.

The propagation directions of the pump and probe beams may be colinear so that the magnetometer counts only one optical access. Alternatively, these propagation directions are orthogonal, or have, as depicted in FIG. 1, an angular offset such that these beams have an area of overlap in the cell.

In an embodiment of the invention depicted in FIG. 1, the magnetometer is a parametric-resonance magnetometer provided with a parametric-resonance excitation circuit that comprises a radio-frequency generator 8 that supplies orthogonal-axis Helmholtz coils 7 that surround the cell in order to generate a radio-frequency magnetic field exciting the parametric resonances. It is in particular possible to provide a pair of Helmholtz coils 7 on each of the axes of the magnetometer so as to generate an excitation radio-frequency field having three orthogonal components. In one example embodiment, Helmholtz coils are used to apply a radio-frequency magnetic field along the z axis, this field having an amplitude of 2.5 μT and a sufficiently high frequency to emerge from the low-frequency noise of the laser emitting the probe beam, for example a frequency of 90 kHz.

In another embodiment, the magnetometer is a Hanle effect magnetometer that is therefore not provided with such a parametric-resonance excitation circuit.

The magnetometer may also comprise a closed-loop control system for the magnetometer in order to constantly subject the cell to a zero total magnetic field. The control system comprises a regulator 9 coupled to the processing electronics, which injects a current into the orthogonal-axis Helmholtz coils (the same as those used by the parametric-resonance excitation circuit in the case of the parametric-resonance magnetometer) that surround the cell 1 in order to generate a compensation magnetic field Bc such that the sum Bc+B₀ is permanently maintained at zero. Alternatively, the magnetometer may be operated in open loop, without any compensation for the ambient field.

FIG. 3 depicts the Voigt profile of the atomic transition line D₀ of helium-4 and particularly the real part of this profile in a solid line and the imaginary part of this profile in a broken line. The real part is representative of the intensity of the pumping while the imaginary part is representative of the intensity of the probe signal. In this figure, the line is centred on the zero frequency, the maximum of the imaginary part is at 943.5 MHz from the centre of the line and the intensities are in an arbitrary unit.

Under the effect of the pump beam, the atoms of the atomic gas undergo an atomic transition. The pump beam may for this purpose be tuned for wavelength at the centre of an atomic transition line, for example on the line D₀ at 1083 nm in the case of helium-4. A wavelength tuned to the centre of a line typically means that the wavelength is separated from the centre of the line by no more than half the full width at half maximum of the line, that is to say at ±0.85 GHz from the centre for the D₀ line of helium.

The probe beam for its part undergoes variations in polarisation while passing through the cell. For the reasons detailed below, the wavelength thereof is ideally close to the centre of the atomic line in order to increase the amplitude of the photodetected signal. The probe beam can for this purpose be tuned for wavelength to the maximum of the imaginary part of the Voigt profile of an atomic transition line (which may or may not be the same as that used for pumping), the wavelength typically being separated from this maximum by no more than one quarter of the full width at half maximum of the line, that is to say at ±0.45 GHz from this maximum for the D₀ line of helium.

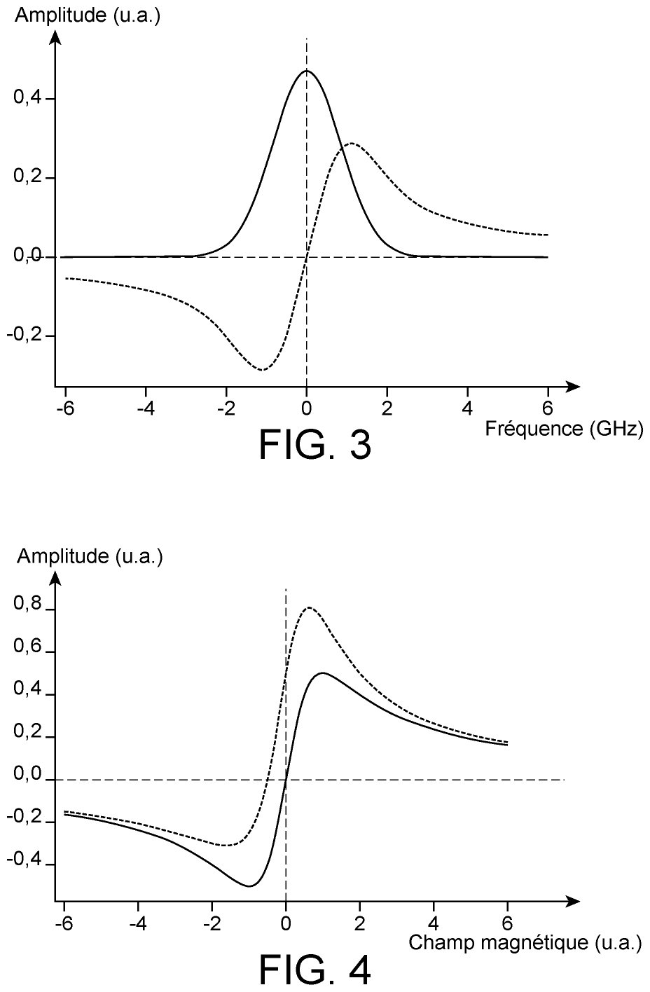

When the roles of the two beams are perfectly separated (i.e. when the probe is not pumping at all the atoms, which can be obtained by moving the wavelength of the probe beam sufficiently far away with respect to any transition allowing pumping), it is possible, with an angle α of 45° and a parametric-resonance magnetometer, to obtain a so-called “dispersive” signal in the domain of the magnetic resonance. The amplitude of this signal, set out in a solid line in FIG. 4 in arbitrary units, is in particular characterised by a linear-magnetic field region around the zero magnetic field, which allows easy measurement of a low-amplitude field (for example of 10 nT).

However, the amplitude of the signal obtained is proportional to the amplitude of the imaginary part of the Voigt profile of the atomic transition used for probing, and therefore decreases by 1/v−vₒ when the wavelength of the probe beam is sufficiently far from the centre of the transition (where 1/v−vₒ represents a wavelength of the probe and v₀ represents the wavelength of the centre of the atomic transition). Thus, in order to increase the amplitude of the signal, it is chosen to move the wavelength of the probe beam close to the centre of the line. This wavelength is then typically separated from the centre of the line by no more than the full width at half maximum of the line, and at least a quarter of this width.

In this case however it is found, from the curve in a broken line in FIG. 4, that the photodetected signal is deformed. This deformation is probably due to the fact that, in moving closer to the centre of the line, the probe also starts to pump the gas, and thus competes with the pumping carried out by the pump beam. This deformation is a problem, in particular because a point corresponding to a zero signal no longer corresponds to a zero magnetic field, which causes a shift in the zero of the magnetometer.

The Applicant has nevertheless been able to find that it is possible, in the case of a parametric-resonance magnetometer, to choose said non-zero angle α so that the signal delivered by the photodetection device is zero when there is a zero ambient magnetic field. With such an angle, the deformation and the shift of the zero are cancelled and it proves possible to find a perfectly dispersive signal shape while benefiting from a higher amplitude of the signal and therefore a better signal-to-noise ratio. In other words, the pumping carried out by the probe supplements the pumping of the pump so as to correct the aforementioned shift.

In the case of the absorption Hanle-effect magnetometer, it will be noted that the signal delivered by the photodetection device has a continuous shift due to the intensity of the probe beam that passes through the gas without being absorbed, on which the magnetic signal is superimposed. However, in general terms, the zero signal that it is sought to obtain when there is a zero ambient magnetic field corresponds to the signal demodulated at the modulation frequency of the system (modulation obtained by the radio frequencies for the parametric resonance, or by a modulation of the probe beam for the Hanle effect magnetometer).

The Applicant has in particular been able to develop the following analytical expression for determining the optimum polarisation angle of the probe in the case of a parametric-resonance magnetometer for which a radio-frequency field is applied on the z axis: Γₛ+Γₚ (cos[α])²−Γₚ (sin[α])²=0,

where Γₛ and Γₚ represent the broadening of the resonance line due to the probe beam and to the pump beam respectively. This is because, “at zero optical power” (that is to say at a very low power of around 1 μW for helium for example), the resonance line has a minimum width (which we refer to as the natural width Γₑ). When the various beams have higher powers, the resonance line is broadened. Its total width then becomes Γₜₒₜ=Γₛ+Γₚ+Γₑ. Typically, Γₜₒₜ is chosen between Γₑ and 4Γₑ. In the limit case Γₜₒₜ=4Γₑ, and, when the two beams are pumping equivalently (Γₛ=Γᵣ), it is necessary to place the polarisation of the probe at an angle α=90°. Beyond (Γ_{probe}>Γₚᵤₘₚ), it is no longer possible to find a perfectly dispersive signal.

In an example embodiment, the wavelength of the pump beam is adjusted to the centre of the line D₀ of helium at 1083.205 nm in vacuum and the wavelength of the probe beam is adjusted to the maximum of the imaginary part of the Voigt profile of this line, that is to say at 943.5 MHz from the centre of the line. The optical powers of the pump and probe beams are adjusted so that the pumping rate of the pump beam is twice as great as the pumping rate of the probe beam (Γₚ=2Γₛ), which leads to having a power of the probe beam 1.175 times greater than the power of the pump beam. In order to obtain a perfectly dispersive signal, it is therefore necessary to use an angle α of 60°

In the case where two RF fields are applied, it is possible to obtain the components of the ambient field along the three axes as described in the article by Morales et al. cited previously. The pumping generated by the probe beam then results in deformations of the three signals corresponding to the three components of the field. In this case, the angle α making it possible to cancel out the shift of the zero cannot be calculated with an expression as simple as that presented above, since the amplitude of the various RF fields also plays a role. However, many tests show that it is always possible experimentally to find an angle that gives the three signals a perfectly dispersive form again. It can also be envisaged finding compromises to give a dispersive form again to only one axis (or two) at a time.

This principle of adjustment of the angle between the linear-polarisation directions of the pump and probe beams remains valid for the configuration of the Hanle effect magnetometer for which the measurement is a measurement of absorption. In order to measure the component of the magnetic field along the z axis, it is also necessary to adjust the angle α so that it satisfies the equation given above and the criterion Γₛ≤Γₚ.

When the magnetometer is of the Hanle effect type, the detector 6 is configured to make a measurement of absorption of the probe beam when passing through the cell.

When the magnetometer is of the parametric-resonance type, the detector 6 comprises a polarisation analyser configured to make a differential measurement of the right-hand circular polarisation σ+ and of the left-hand circular polarisation σ− of the probe beam that has passed through the cell. The detector 6 thus delivers, as a signal carrying information relating to the state of alignment of the atoms of the atomic gas in the cell, a signal representing the difference between the intensities of the right-hand and left-hand circular polarisations. This signal depends solely on the component of the magnetic field along the z axis and, as depicted by the curve in a solid line in FIG. 3, has the form of a dispersive Lorentzian curve centred in zero field. It should be noted that the concern here is also with the part of the optical signal modulated at the frequency of the radio-frequency field exciting the parametric resonance.

The polarisation analyser can in particular be configured to effect a spatial separation of the right-hand and left-hand circular polarisations of the probe beam that has passed through the cell. For this purpose, the polarisation analyser may comprise a quarter-wave plate, a polarisation-separator cube able to separate, on a first and second path, the right-hand circular polarisation and the left-hand circular polarisation of the probe contribution that has passed through the cell and a photodetector on each of the first and second paths.

When the magnetometer is operated in Hanle effect, it may also comprise a modulator for the probe beam. The probe beam can thus be modulated in amplitude and polarisation or even in wavelength in a degraded mode of implementation of an amplitude modulation. The modulation frequency may be sufficiently high, for example around 30 kHz, to eliminate the problems of low-frequency noise of the laser providing the probe beam, without losing in signal amplitude. The modulator of the probe beam may also be a polarisation modulator, for example a photoacoustic modulator, arranged between the measuring cell and the detector.

The invention also relates to a method for measuring a magnetic field by means of the magnetometer as previously described. This method comprises in particular the steps consisting of linearly polarising the pump beam in a polarisation direction, and linearly polarising the probe beam in a polarisation direction that forms a non-zero angle with the polarisation direction of the pump beam.

What is claimed is:

1. A magnetometer comprising:
a cell filled with an atomic gas,
an optical source configured to illuminate the cell with a pump beam and a probe beam, and
a photodetection device arranged so as to receive the light of the probe beam that has passed through the cell and configured to deliver a signal carrying information relating to the state of alignment of the atoms of the atomic gas in the cell,
wherein the pump beam is polarised linearly in a polarisation direction and the probe beam is polarised linearly in a polarisation direction forming a non-zero angle with the polarisation direction of the pump beam.

2. The magnetometer according to claim 1, wherein the probe beam propagates along the z axis of an Oxyz trihedron having a x axis, a y axis and a z axis, the pump beam is polarised linearly along the x axis of the Oxyz trihedron and the pump beam is polarised linearly in a plane defined by the x and y axis, making said non-zero angle with the x axis.

3. The magnetometer according to claim 1, wherein the signal delivered by the photodetection device is zero when there is a zero ambient magnetic field.

4. The magnetometer according to claim 1, wherein said non-zero angle is between 45° and 90°.

5. The magnetometer according to claim 1, wherein the pump beam is tuned for wavelength at the centre of a first atomic line and the probe beam is tuned for wavelength so as to be offset from the centre of a second atomic line different from the first atomic line.

6. The magnetometer according to claim 1, wherein the pump beam is tuned for wavelength at the centre of a first atomic line and the probe beam is tuned for wavelength so as to be offset from the centre of the first atomic line.

7. The magnetometer according to claim 1, further comprising a parametric-resonance excitation source and wherein the photodetection device comprises a polarisation analyser configured to make a differential measurement of a right-hand circular polarisation and of a left-hand circular polarisation of the probe beam that has passed through the cell.

8. The magnetometer according to claim 7, wherein the polarisation analyser comprises a quarter-wave plate, a polarisation separator cube able to separate, on a first path and a second path, the right-hand circular polarisation and the left-hand circular polarisation of the probe contribution that has passed through the cell and a photodetector on each of the first and second paths.

9. The magnetometer according to claim 1, wherein the photodetection device is configured to make an absorption measurement of the probe beam on passing through the cell.

10. The magnetometer according to claim 1, further comprising a modulator of the probe beam.

11. A method for measuring a magnetic field by means of a magnetometer comprising a cell filled with an atomic gas, an optical source configured to illuminate the cell with a pump beam and a probe beam, and a photodetection device arranged so as to receive the light of the probe beam that has passed through the cell and configured to deliver a signal carrying information relating to the state of alignment of the atoms of the atomic gas in the cell, the method comprising the steps of:
linearly polarising the pump beam in a polarisation direction, and
linearly polarising the probe beam in a polarisation direction that forms a non-zero angle with the polarisation direction of the pump beam.
